(19) United States
(12) Patent Application Publication
(10) Pub. No.: US 2024/0180039 A1
(43) Pub. Date: May 30, 2024

(54) METHOD OF MANUFACTURING MULTILAYER PIEZOELECTRIC ELEMENT INCLUDING INTERNAL ELECTRODES

(71) Applicant: KOREA ELECTRONICS TECHNOLOGY INSTITUTE, Seongnam-si (KR)

(72) Inventors: Intae SEO, Gwangju-si (KR); Hyung Won KANG, Seoul (KR); Seung Ho HAN, Gwacheon-si (KR)

(73) Assignee: KOREA ELECTRONICS TECHNOLOGY INSTITUTE, Seongnam-si (KR)

(21) Appl. No.: 18/521,287

(22) Filed: Nov. 28, 2023

(30) Foreign Application Priority Data
Nov. 29, 2022 (KR) 10-2022-0163185

(51) Int. Cl. H10N 30/053; C22C 9/06; H10N 30/067; H10N 30/50; H10N 30/87

(52) U.S. Cl. CPC H10N 30/053; C22C 9/06; H10N 30/067; H10N 30/50; H10N 30/871; H10N 30/877

(57) ABSTRACT

Disclosed is a method of manufacturing a multilayer piezoelectric element including internal electrodes, including providing a piezoelectric sheet including ceramic, forming internal electrodes on the piezoelectric sheet to create a piezoelectric sheet with internal electrodes formed thereon, stacking a plurality of piezoelectric sheets with internal electrodes formed thereon to create a piezoelectric stack, sintering the piezoelectric stack to create a sintered piezoelectric stack, and heat-treating the sintered piezoelectric stack in a reducing atmosphere, in which the internal electrodes are formed in an area ratio of 90% or more relative to the area of the piezoelectric sheet, thereby facilitating reduction of the internal electrodes even by reduction heat treatment at a relatively low temperature.

### CROSS REFERENCE TO RELATED APPLICATION

The present application claims priority to Korean Patent Application No. 10-2022-0163185, filed Nov. 29, 2022, the entire contents of which is incorporated herein for all purposes by this reference.

### BACKGROUND OF THE INVENTION

### Field of the Invention

The present disclosure relates to a method of manufacturing a multilayer piezoelectric element including internal electrodes.

### Description of the Related Art

Multilayer piezoelectric ceramic elements such as MLCCs (multi-layer ceramic capacitors) require both internal electrodes and ceramics to be sintered. Conventionally, a process of sintering internal electrodes and ceramics simultaneously was adopted, and a reducing atmosphere was applied to prevent internal electrodes from being oxidized during simultaneous sintering of internal electrodes and ceramics. Recently, research has been continuously conducted on methods of reducing oxidized internal electrodes while minimizing defects in ceramics by performing reduction heat treatment at a relatively low temperature after sintering a multilayer piezoelectric ceramic element in an ambient atmosphere.

### CITATION LIST

### Patent Literature

(Patent Document 1) KR 10-2340484 B1

### DISCLOSURE

### Technical Problem

The present disclosure is intended to provide a method of manufacturing a multilayer piezoelectric element, which allows internal electrodes to react with a reducing gas even at a relatively low temperature while maintaining high ceramic sintering density.

### Technical Solution

A first aspect of the present disclosure provides a method of manufacturing a multilayer piezoelectric element including internal electrodes, including providing a piezoelectric sheet including ceramic, forming internal electrodes on the piezoelectric sheet to create a piezoelectric sheet with internal electrodes formed thereon, stacking a plurality of piezoelectric sheets with internal electrodes formed thereon to create a piezoelectric stack, sintering the piezoelectric stack to create a sintered piezoelectric stack, and heat-treating the sintered piezoelectric stack in a reducing atmosphere, in which the internal electrodes are formed in an area ratio of 90% or more relative to the area of the piezoelectric sheet.

According to an embodiment of the present disclosure, in providing the piezoelectric sheet, the piezoelectric sheet may be manufactured from raw materials for manufacturing a piezoelectric sheet including ceramic powder, and may include ceramic selected from the group consisting of PZT (lead zirconate titanate), PMN (lead magnesium niobate), PMN (lead manganese niobate), PZN (lead zinc niobate), PNN (lead nickel niobate), PSN (lead antimony niobate), PCN (lead copper niobate), PZNN (lead zinc nickel niobate), lead-free KNN (potassium sodium niobate), BT (barium titanate), NBT (sodium bismuth titanate), and combinations thereof.

According to an embodiment of the present disclosure, the particle size of the ceramic powder may be 0.1 μm or more.

According to an embodiment of the present disclosure, providing the piezoelectric sheet may further include tape-casting raw materials for manufacturing a piezoelectric sheet and drying the piezoelectric sheet, wherein drying the piezoelectric sheet may be performed in a three-stage temperature gradient, with a temperature of first drying ≤ a temperature of second drying ≤ a temperature of third drying.

According to an embodiment of the present disclosure, the internal electrodes may include a metal selected from the group consisting of Ag, Cu, Pt, Ni, Pd, Au, W, Sn, and combinations thereof.

According to an embodiment of the present disclosure, the internal electrodes may include a combination of Cu and Ni, in which the amount of Ni may be 10 to 20 wt % based on the total weight of the internal electrodes.

According to an embodiment of the present disclosure, in forming the internal electrodes, the internal electrodes may be formed by screen printing or electroless plating.

According to an embodiment of the present disclosure, sintering the piezoelectric stack may be performed at a temperature of 700 to 1000° C.

According to an embodiment of the present disclosure, heat-treating the sintered piezoelectric stack in a reducing atmosphere may be performed at a temperature of 250 to 400° C.

According to an embodiment of the present disclosure, the reducing atmosphere may include 3 to 10 vol % of hydrogen.

### Advantageous Effects

According to the first aspect of the present disclosure, there can be provided a multilayer piezoelectric element with superior piezoelectric properties by reducing internal electrodes while minimizing damage to a ceramic piezoelectric sheet.

### BRIEF DESCRIPTION OF THE DRAWINGS

The above and other aspects, features, and other advantages of the present disclosure will be more clearly understood from the following detailed description taken in conjunction with the accompanying drawings, in which:

FIGS. 1A to 1D are plan views of piezoelectric sheets with internal electrodes formed thereon according to an embodiment and a comparative example;

FIG. 2 shows polarization hysteresis curves of the multilayer piezoelectric elements according to an embodiment and a comparative example;

FIGS. 3A to 3D are SEM images showing the extent of reduction of internal electrodes depending on the sintering temperature in the multilayer piezoelectric element according to an embodiment;

FIGS. 4A to 4D are SEM images showing the extent of reduction of internal electrodes depending on the sintering temperature in the multilayer piezoelectric element according to a comparative example;

### DETAILED DESCRIPTION OF THE INVENTION

Aspects, advantages, and features of the present disclosure will become more apparent from the following detailed description and embodiments taken in conjunction with the accompanying drawings, but the present disclosure is not necessarily limited thereto. In addition, when describing the present disclosure, if it is determined that a detailed description of related known technology may unnecessarily obscure the gist of the present disclosure, the detailed description will be omitted.

An aspect of the present disclosure pertains to a method of manufacturing a multilayer piezoelectric element including internal electrodes, including providing a piezoelectric sheet including ceramic, forming internal electrodes on the piezoelectric sheet to create a plurality of piezoelectric sheets with internal electrodes formed thereon, stacking the piezoelectric sheets with internal electrodes formed thereon to create a piezoelectric stack, sintering the piezoelectric stack to create a sintered piezoelectric stack, and heat-treating the sintered piezoelectric stack in a reducing atmosphere, in which the internal electrodes are formed in an area ratio of 90% or more relative to the area of the piezoelectric sheet.

Providing the piezoelectric sheet is a step of manufacturing a piezoelectric sheet including ceramic and applying the same to a method of manufacturing a multilayer piezoelectric element including internal electrodes. Here, “the internal electrodes” are electrodes formed on the piezoelectric sheet including ceramic, and serve to improve piezoelectric properties of a multilayer piezoelectric element by being alternately stacked with piezoelectric sheets in a final product, namely a multilayer piezoelectric element. Ceramic included in the piezoelectric sheet may be added in the form of ceramic powder to raw materials for manufacturing a piezoelectric sheet, and examples thereof may include, but are not limited to, ceramic powder having piezoelectric properties, such as PZT (lead zirconate titanate), PMN (lead magnesium niobate), PMN (lead manganese niobate), PZN (lead zinc niobate), PNN (lead nickel niobate), PSN (lead antimony niobate), PCN (lead copper niobate), PZNN (lead zinc nickel niobate), and combinations thereof. Any ceramic powder having piezoelectric properties may be used without limitation. In particular, ceramic powder, including lead-free KNN (potassium sodium niobate), BT (barium titanate), or NBT (sodium bismuth titanate) piezoelectric ceramic powder, which does not contain toxic Pb, and combinations thereof, may also be used.

The particle size of the ceramic powder may be 0.1 μm or more. Since the piezoelectric properties of ceramic powder are significantly deteriorated at a size less than 0.1 μm, when mixing the raw materials for manufacturing the piezoelectric sheet by milling, it is necessary to control the milling intensity so that the ceramic powder is not excessively pulverized.

The raw materials for manufacturing the piezoelectric sheet may include, in addition to the ceramic powder, a polymer binder such as PVB, a plasticizer such as DBP (dibutyl phthalate), DEHP (diethylhexyl phthalate), BBP (butylbenzyl phthalate), DINP (diisononyl phthalate), or DIDP (diisodecyl phthalate), and a solvent such as methanol and benzene, and the method may further include mixing the raw materials for manufacturing the piezoelectric sheet, including the ceramic powder and the components listed above, to prepare a slurry. Here, any mixing process may be performed without limitation, and the raw materials for manufacturing the piezoelectric sheet may be mixed, for example, by stirring or milling.

Providing the piezoelectric sheet may further include tape-casting the raw materials for manufacturing the piezoelectric sheet and drying the piezoelectric sheet. Here, the drying may be performed in a three-stage temperature gradient, with the temperature of the first drying ≤ the temperature of the second drying ≤ the temperature of the third drying. Tape casting is a kind of roll-to-roll process that produces a sheet-type material in a large area. The raw materials for manufacturing the piezoelectric sheet may be tape-cast into a piezoelectric sheet having a planar shape.

Drying the piezoelectric sheet is a step of volatilizing the solvent having a predetermined boiling point from the manufactured piezoelectric sheet, and may be performed at a temperature of 40 to 150° C. in consideration of the boiling point of the solvent. More specifically, the drying may be performed in a three-stage temperature gradient, with the temperature of the first drying ≤ the temperature of the second drying ≤ the temperature of the third drying. The first drying may be performed at 40 to 80° C., the second drying may be performed at 60 to 120° C., and the third drying may be performed at 100 to 150° C. The three-stage drying described above makes it possible to prevent the piezoelectric composite sheet from damage due to a rapid increase in temperature and suppress the sheet from lifting during the tape casting process.

The method includes forming the internal electrodes. The internal electrodes function as electrodes and simultaneously impart higher piezoelectric properties to the piezoelectric composite sheet. The internal electrodes are made of a metal selected from the group consisting of Ag, Cu, Pt, Ni, Pd, Au, W, Sn, and combinations thereof, but the metal is not limited thereto. Any metal may be used without limitation, so long as it is able to be formed in a predetermined pattern on a piezoelectric composite sheet.

In an embodiment, the internal electrodes may include a combination of Cu and Ni. Here, the amount of Ni may be 10 wt % to 50 wt %, or 10 to 20 wt %, based on the total weight of the internal electrodes. In general, the ceramic of the piezoelectric sheet and the internal electrodes have different shrinkage rates when sintered, and particularly, the shrinkage rate of the internal electrodes is higher than that of the ceramic. This is called sintering mismatch between the piezoelectric sheet and the electrodes, which may cause problems such as specimen deformation, delamination, electrode isolation, and the like. This phenomenon is also associated with the low melting point of the internal electrodes. As described above, when the amount of Ni in the internal electrodes is 10 wt % or more, the melting point of Ni is higher than the melting point of additional metal such as Cu in the internal electrodes, so the shrinkage rate of the internal electrodes may be controlled to a level similar to that of the piezoelectric sheet, which may advantageously prevent the sintering mismatch as described above. On the other hand, if the amount of Ni exceeds 50 wt %, low-temperature reduction heat treatment may become difficult. Specifically, the internal electrodes according to an embodiment include 10 wt % to 50 wt % of Ni based on the total weight thereof from the viewpoint of minimizing sintering mismatch with the ceramic of the piezoelectric sheet and lowering the reduction heat treatment temperature.

There is no limitation as to a process of forming the internal electrodes, but from the viewpoint of mass production and formation of a pattern on a sheet-type piezoelectric composite material, screen printing or electroless plating may be performed.

The method includes stacking the piezoelectric sheets with internal electrodes formed thereon to create a piezoelectric stack. When a piezoelectric stack formed by stacking the piezoelectric sheets with the same internal electrodes formed thereon is observed from above, all internal electrodes formed on individual sheets are present at the same position with respect to the piezoelectric sheets. In an embodiment, 3 to 50, or 5 to 10 piezoelectric sheets having internal electrodes may be stacked. In theory, the number of piezoelectric sheets that are stacked is not limited, but taking into consideration the thickness of each piezoelectric sheet, when stacking more than 50 piezoelectric sheets, problems such as distortion of sheets and accumulation of distortion in portions where internal electrodes are not formed may occur. Moreover, the multilayer piezoelectric element of the present disclosure requires low capacitance for low-power operation, and thus, the number of piezoelectric sheets that are stacked may be set to 50 or less from the viewpoint of suppressing excessive capacitance.

The method includes sintering the piezoelectric stack to create a sintered piezoelectric stack. Sintering the piezoelectric stack is a step of heating the piezoelectric stack to volatilize the binder that may be present in the piezoelectric sheet and densifying ceramic powder bonds. Sintering the piezoelectric stack may be performed in an ambient atmosphere, and during this process, since the internal electrodes, as well as the piezoelectric sheets of the piezoelectric stack, may come into contact with a high-temperature atmosphere, the internal electrodes may be oxidized, and oxidation of the internal electrodes may deteriorate piezoelectric properties.

According to an embodiment, sintering the piezoelectric stack may be performed at a temperature of 700 to 1000° C. If the sintering temperature is lower than 700° C., ceramic densification may not be easy, whereas if it exceeds 1000° C., the internal electrodes may melt.

The method includes heat-treating the sintered piezoelectric stack in a reducing atmosphere. As described above, when the piezoelectric stack is introduced to a high-temperature ambient atmosphere for ceramic densification during sintering, the internal electrodes may also be oxidized due to contact with the high-temperature ambient atmosphere, so the electrodes have to be reduced through reduction reaction by contact with a reducing gas. Here, the internal electrodes are present inside the piezoelectric sheet that is densified during sintering described above, so it is difficult for the reducing gas to reach the internal electrodes inside the densified piezoelectric sheet. Accordingly, the method provides a high-temperature environment that facilitates diffusion of the reducing gas by performing heat treatment such that the reducing gas is able to reach the internal electrodes.

According to an embodiment, reduction heat treatment may be performed at a temperature of 250 to 400° C., which is regarded as lower than the heat treatment temperature for a conventional reduction heat treatment process. If the reduction heat treatment temperature is lower than 250° C., it is not easy for the reducing gas to reach the internal electrodes, making it difficult to reduce the internal electrodes. On the other hand, if the reduction heat treatment temperature exceeds 400° C., oxygen vacancies may be generated in the ceramic of the piezoelectric sheet that is densified by sintering, or damage to the piezoelectric sheet may occur due to volatilization of individual elements. The reduction heat treatment may be performed at a temperature of 250 to 320° C., or 250 to 300° C.

According to an embodiment, the reducing atmosphere may include 0.1 to 10 vol % of hydrogen. The reduction heat treatment may be performed under a reducing atmosphere to reduce the internal electrodes, and may include a reducing gas such as hydrogen. Moreover, the reducing atmosphere may include an inert gas such as nitrogen in addition to the reducing gas. If the amount of hydrogen in the reducing atmosphere is less than 0.1 vol %, it is difficult to reduce the oxidized internal electrode s because the reducing atmosphere is composed mainly of inert gas, whereas if the amount of hydrogen in the reducing atmosphere exceeds 10 vol %, process stability may be deteriorated due to explosion of hydrogen. In an embodiment, the reducing atmosphere may include 2 to 10 vol % of hydrogen, or 4 to 8 vol % of hydrogen.

In the method, the internal electrodes are formed in an area ratio of 90% or more relative to the area of the piezoelectric sheet. The internal electrodes of the present disclosure are formed in an area ratio of 90% or more relative to the area of the piezoelectric sheet, making it easy for the reducing gas to reach the internal electrodes through the ceramic densified by sintering in the piezoelectric stack even at the relatively low reduction heat treatment temperature as described above. Even when the ceramic is densified, the reducing gas may pass therethrough, and the area occupied by the internal electrodes in each of the piezoelectric sheets stacked as described above may be maximized, thus minimizing the amount of piezoelectric sheets including ceramic that may exist between the external atmosphere and the internal electrodes in the piezoelectric stack, thereby enabling reduction of the internal electrodes at a relatively low reduction heat treatment temperature. Particularly, the internal electrodes may be formed in an area ratio of 95% or more relative to the area of the piezoelectric sheet, and more particularly, the internal electrodes may be formed in an area ratio of 99% or more relative to the area of the piezoelectric sheet.

In an embodiment, the portion (ceramic margin) of the piezoelectric sheet in which the internal electrodes are not formed may be formed to have a distance of 5% or more of the maximum dimension of the piezoelectric sheet from at least one side of the piezoelectric sheet. In an embodiment, when the piezoelectric sheet is a square of 10 cm×10 cm, the ceramic margin portion may be formed to have a distance of 0.5 cm or more from at least one side of the piezoelectric sheet. When the ceramic margin portion of the piezoelectric sheet has the above pattern, the internal electrodes in the piezoelectric stack may be exposed to the outside, which may facilitate reduction of the internal electrodes during reduction heat treatment. In an embodiment, the portion of the piezoelectric sheet in which the internal electrodes are not formed may be formed to have a distance of 10% or more, or 20% or more, of the maximum dimension of the piezoelectric sheet from at least one side of the piezoelectric sheet.

A better understanding of the present disclosure may be obtained through the following examples. However, these examples are merely set forth to illustrate the present disclosure, and are not to be construed as limiting the present disclosure.

### Preparation Example 1—Manufacture of Multilayer Piezoelectric Element Including Internal Electrodes

A piezoelectric sheet manufactured by tape casting was cut to a predetermined size of 10 cm×10 cm, and then alignment holes were formed at four corners of the cut square sheet using an automatic punching machine. Internal electrodes were formed by printing a Cu/Ni electrode paste in a pattern at regular intervals on the piezoelectric sheet using a screen mask based on the formed alignment holes. The amount of Ni in Cu/Ni internal electrodes was 20%.

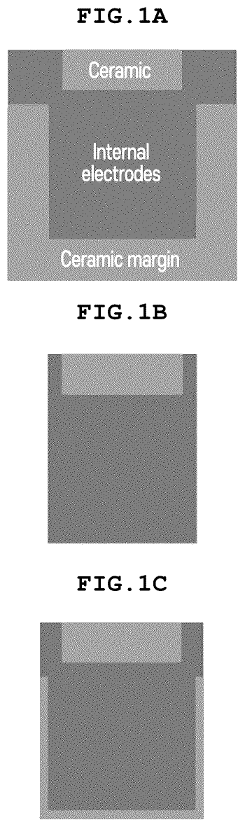

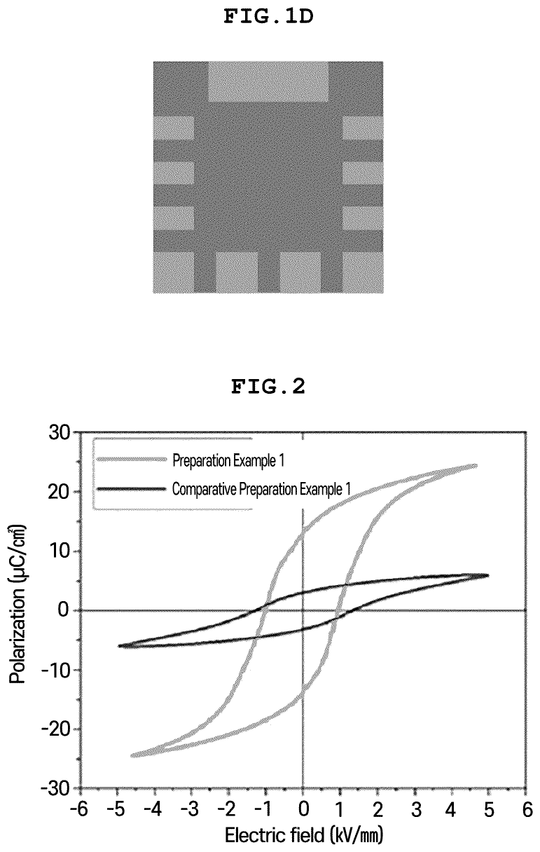

In forming the internal electrodes, the shape and ratio of the portion of the piezoelectric sheet in which the internal electrodes are not formed (ceramic margin) may be variously changed as shown in FIGS. 1B to 1D, so that the internal electrodes are well exposed to the outside. In Preparation Example 1, the internal electrodes were formed in an area ratio of 95% relative to the area of the piezoelectric sheet, and the piezoelectric sheet with the internal electrodes formed in this way is shown in FIG. 1B.

A plurality of piezoelectric sheets with internal electrodes formed thereon was stacked so that the electrode patterns of individual piezoelectric sheets were aligned, and then pressed at 60° C. under a pressure of 1 ton for 20 seconds. Thereafter, the resulting stack was sealed and then subjected to cold isostatic pressing (CIP) to increase adhesion between the piezoelectric sheets and remove the internal air layer, thus forming a piezoelectric stack.

The piezoelectric stack was cut along the printed pattern and then sintered in an ambient atmosphere at a temperature of 900° C. to create a sintered piezoelectric stack. Thereafter, the internal electrodes were reduced through reduction heat treatment at 400° C. in a 5% H₂ atmosphere, thereby manufacturing a multilayer piezoelectric element.

### Comparative Preparation Example 1

A multilayer piezoelectric element was manufactured in the same manner as in Preparation Example 1, with the exception that the internal electrodes were formed in an area ratio of 70% relative to the area of the piezoelectric sheet. As shown in FIG. 1A, the area occupied by the ceramic margin in the cross-section of the piezoelectric sheet with internal electrodes of Comparative Preparation Example 1 was confirmed to be larger than that of Preparation Example 1.

### Example 1—Measurement of Piezoelectric Properties of Multilayer Piezoelectric Element

In order to evaluate a difference in piezoelectric properties depending on the internal electrode area ratio of the multilayer piezoelectric elements manufactured in Preparation Example 1 and Comparative Preparation Example 1, they were subjected to polarization treatment by applying an electric field of 4 kV/mm for 1 hour in Si oil at 100° C., after which ferroelectric properties represented by hysteresis curves were confirmed. The hysteresis curves based on the above measurement are as shown in FIG. 2.

Referring to FIG. 2, after applying an electric field, when the applied electric field returns to 0, the sample of Preparation Example 1 shows a polarization of about 15 μC/cm², which was observed that superior ferroelectric properties were exhibited compared to the sample of Comparative Preparation Example 1 showing a polarization of less than 5 μC/cm² under the same conditions. Considering the above observation results and that the manufacturing conditions other than the area ratio of the internal electrodes were the same, it could be inferred that, due to the high area ratio of the internal electrodes of the sample of Preparation Example 1, the internal electrodes were more easily reduced during reduction heat treatment, and the sample of Preparation Example 1 exhibited high polarization properties.

### Preparation Example 2 and Comparative Preparation Example 2

Multilayer piezoelectric element samples of Preparation Example 2 were manufactured under the same conditions as in Preparation Example 1, with the exception that only the sintering temperature during sintering was changed to 850° C., 875° C., 900° C., and 925° C.

Likewise, multilayer piezoelectric element samples of Comparative Preparation Example 2 were manufactured under the same conditions as in Comparative Preparation Example 1, with the exception that only the sintering temperature during sintering was changed to 850° C., 875° C., 900° C., and 925° C.

### Example 2—Evaluation of Extent of Internal Electrode Reduction and Ceramic Densification

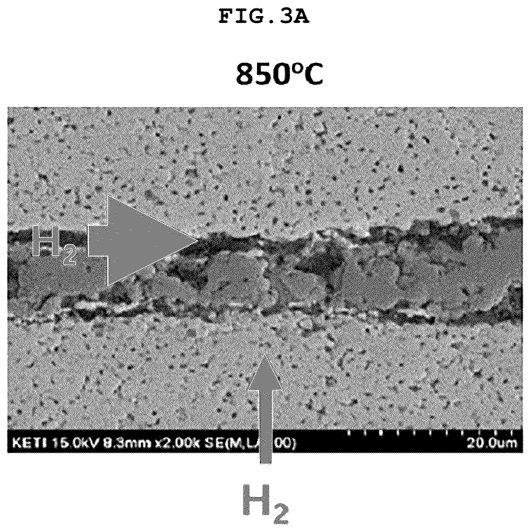

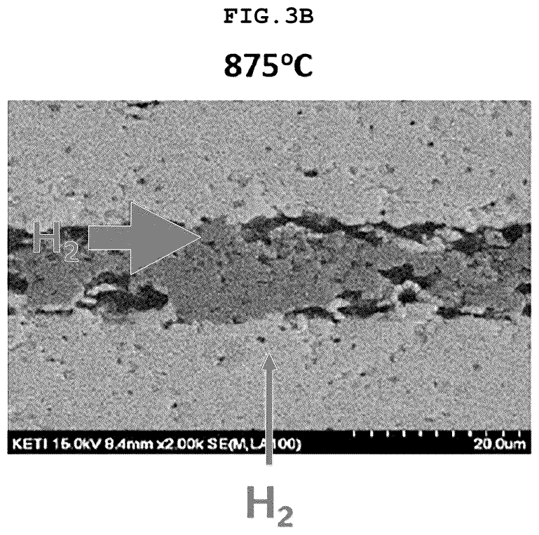

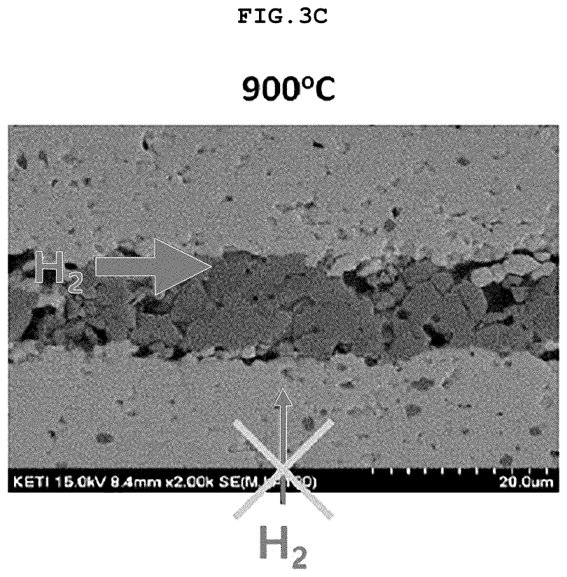

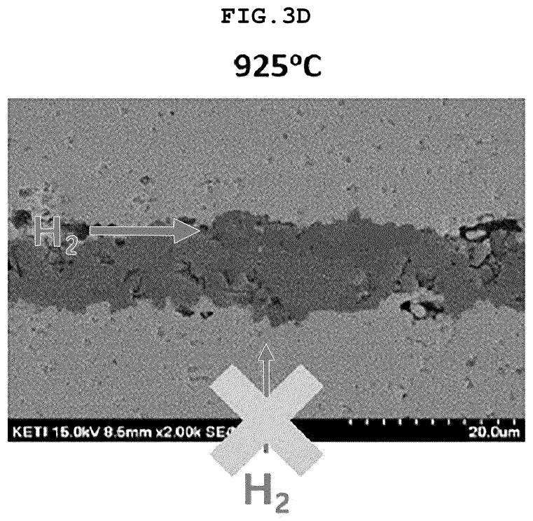

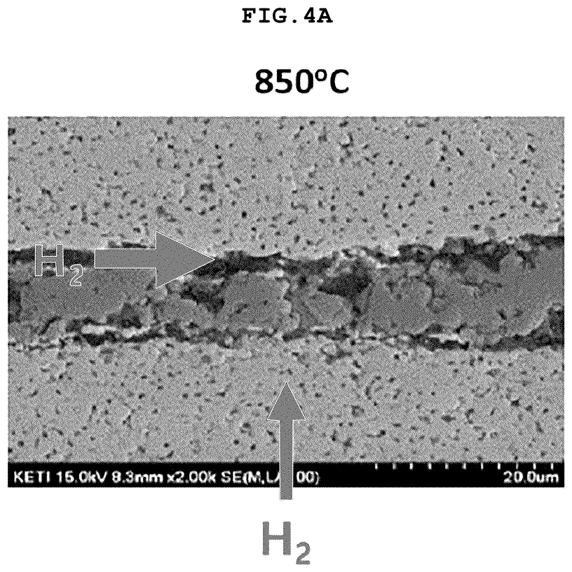

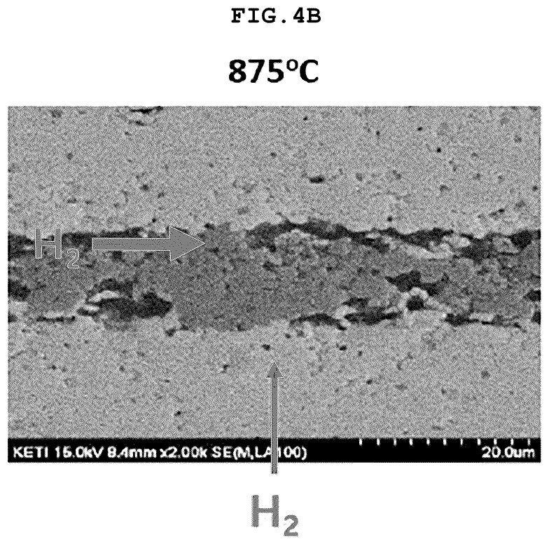

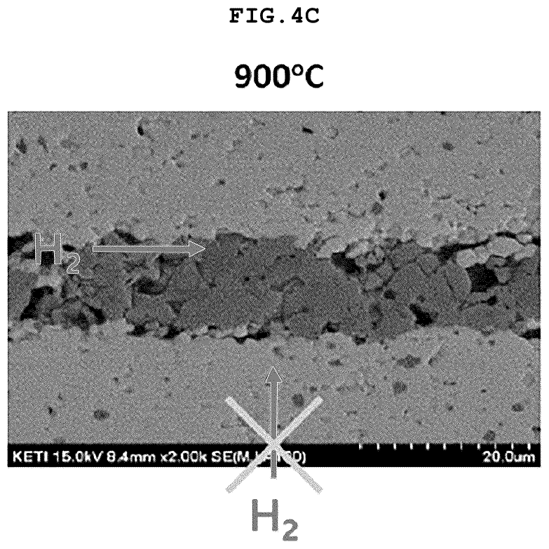

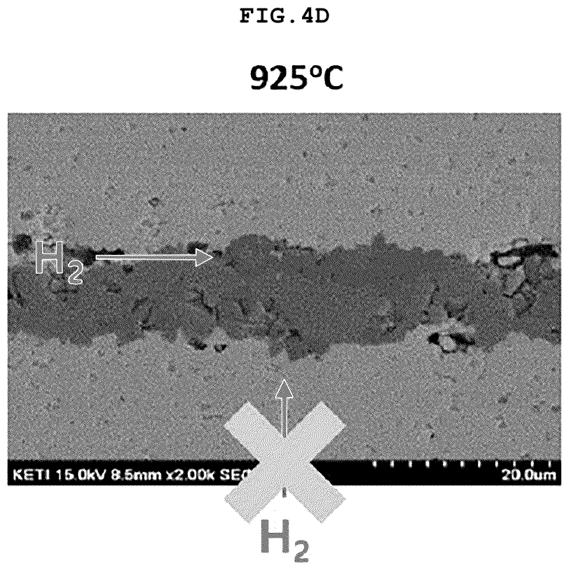

The four samples of Preparation Example 2 and the four samples of Comparative Preparation Example 2 were cut in the stacked direction, and the cut cross-sections were first observed with the naked eye, and then observed with a scanning electron microscope to obtain SEM images. The observation results are shown in Table 1 below, the SEM images for the samples of Preparation Example 2 are shown in FIGS. 3A to 3D, and the SEM images for the samples of Comparative Preparation Example 2 are shown in FIGS. 4A to 4D.

TABLE 1

| Reduction conditions | | | |
|---|---|---|---|
| 5% H₂/400° C. | | | |
| Sintering temperature | | | |
| 850° C. | 875° C. | 900° C. | 925° C. |
| @ Air | @ Air | @ Air | @ Air |

Preparation Example 2

| | | | | |
|---|---|---|---|---|
| Internal | Brown | Brown | Brown | Black |
| electrode color | | | | |
| Extent of internal | Full | Full | Full | Partial |
| electrode reduction | reduction | reduction | reduction | reduction |
| Ceramic density | Low | Medium-high | High | High |

Comparative Preparation Example 2

| | | | | |
|---|---|---|---|---|
| Internal | Brown | Brown + | Black | Black |
| electrode color | | black | | |
| Extent of internal | Full | Partial | X | X |
| electrode reduction | reduction | reduction | | |
| Ceramic density | Low | Medium-high | High | High |

Referring to Table 1, when the sintering temperature was 850° C., the density of the sintered ceramic was low, and in both Preparation Example 2 and Comparative Preparation Example 2, the internal electrodes were fully reduced even at the low reduction heat treatment temperature, but when the sintering temperature was increased to 875° C. and the ceramic became denser, a difference occurred in the extent of reduction of the internal electrodes. Moreover, it was confirmed that the internal electrodes of the samples of Comparative Preparation Example 2 were not reduced at all at sintering temperatures of 900° C. or higher, whereas the sample of Preparation Example 2 was partially reduced even at a sintering temperature of 925° C.

Based on the above measurement results, the effect of the area ratio of the internal electrodes on the extent of oxidation of the internal electrodes during low-temperature reduction heat treatment of the internal electrodes was confirmed.

The present disclosure has been described in detail above through specific embodiments. The embodiments are for specifically explaining the present disclosure, and the present disclosure is not limited thereto. It will be clear that modifications and improvements can be made by those skilled in the art within the technical spirit of the present disclosure.

Simple modifications or variations of the present disclosure fall within the scope of the present disclosure as defined in the accompanying claims.

What is claimed is:

1. A method of manufacturing a multilayer piezoelectric element comprising internal electrodes, comprising:
providing a piezoelectric sheet comprising ceramic;
forming internal electrodes on the piezoelectric sheet to create a piezoelectric sheet with internal electrodes formed thereon;
stacking a plurality of piezoelectric sheets with internal electrodes formed thereon to create a piezoelectric stack;
sintering the piezoelectric stack to create a sintered piezoelectric stack; and
heat-treating the sintered piezoelectric stack in a reducing atmosphere,
wherein the internal electrodes are formed in an area ratio of 90% or more relative to an area of the piezoelectric sheet.

2. The method according to claim 1, wherein, in providing the piezoelectric sheet, the piezoelectric sheet is manufactured from raw materials for manufacturing a piezoelectric sheet comprising a ceramic powder, and comprises ceramic selected from the group consisting of PZT (lead zirconate titanate), PMN (lead magnesium niobate), PMN (lead manganese niobate), PZN (lead zinc niobate), PNN (lead nickel niobate), PSN (lead antimony niobate), PCN (lead copper niobate), PZNN (lead zinc nickel niobate), lead-free KNN (potassium sodium niobate), BT (barium titanate), NBT (sodium bismuth titanate), and combinations thereof.

3. The method according to claim 2, wherein a particle size of the ceramic powder is 0.1 μm or more.

4. The method according to claim 1, wherein providing the piezoelectric sheet further comprises tape-casting raw materials for manufacturing a piezoelectric sheet and drying the piezoelectric sheet, and drying the piezoelectric sheet is performed in a three-stage temperature gradient, with a temperature of first drying ≤ a temperature of second drying ≤ a temperature of third drying.

5. The method according to claim 1, wherein the internal electrodes comprise a metal selected from the group consisting of Ag, Cu, Pt, Ni, Pd, Au, W, Sn, and combinations thereof.

6. The method according to claim 5, wherein the internal electrodes comprise a combination of Cu and Ni, in which an amount of Ni is 10 to 50 wt % based on a total weight of the internal electrodes.

7. The method according to claim 1, wherein, in forming the internal electrodes, the internal electrodes are formed by screen printing or electroless plating.

8. The method according to claim 1, wherein sintering the piezoelectric stack is performed at a temperature of 700 to 1000° C.

9. The method according to claim 1, wherein heat-treating the sintered piezoelectric stack in a reducing atmosphere is performed at a temperature of 250 to 400° C.

10. The method according to claim 1, wherein the reducing atmosphere comprises 0.1 to 10 vol % of hydrogen.
